(19) United States
(12) Patent Application Publication
(10) Pub. No.: US 2014/0211440 A1
(43) Pub. Date: Jul. 31, 2014

(54) CABINET FOR THIN DISPLAY DEVICE AND THIN DISPLAY DEVICE

(71) Applicants: Noriyuki Shibuya, Osaka-shi (JP); Hideaki Nishizawa, Osaka-shi (JP); Masaya Fujihara, Osaka-shi (JP); Takashi Kumashiro, Osaka-shi (JP); Yutaka Yoshizawa, Osaka-shi (JP); Manabu Shimokobe, Osaka-shi (JP)

(72) Inventors: Noriyuki Shibuya, Osaka-shi (JP); Hideaki Nishizawa, Osaka-shi (JP); Masaya Fujihara, Osaka-shi (JP); Takashi Kumashiro, Osaka-shi (JP); Yutaka Yoshizawa, Osaka-shi (JP); Manabu Shimokobe, Osaka-shi (JP)

(73) Assignee: SHARP KABUSHIKI KAISHA, Osaka-shi, Osaka (JP)

(21) Appl. No.: 14/236,835

(22) PCT Filed: May 24, 2012
(86) PCT No.: PCT/JP2012/063286

§ 371 Date: Apr. 4, 2014

(30) Foreign Application Priority Data
Aug. 4, 2011 (JP) 2011-170968
Sep. 15, 2011 (JP) 2011-201568

(51) Int. Cl. H05K 7/02

(52) U.S. Cl. CPC H05K 7/02
USPC 361/772; 174/545

(57) ABSTRACT

Provided is technology that stably fixes a plurality of harnesses all at once, without using a wire holder. A line-shaping section 30 for routing harnesses 99 is created in a front cabinet forming section 20. The line-shaping section 30 comprises two ribs 40 separated by a prescribed distance and a hook 50 positioned in the center thereof and created so as to cover from the top, when viewed from the side surface. The harnesses 99 held by the ribs 40 and the hook are prevented from being displaced outside, by a hook locking section 54. In addition, routing work for the harnesses 99 is able to be performed smoothly since a sloping surface (a guide section 56) is created in a tip part of the hook locking section 54.

### TECHNICAL FIELD

The present invention relates to a cabinet for a thin display device and a thin display device and, for example, relates to a cabinet for a thin display device provided with a structure for fixing wirings of a speaker and the like and a thin display device.

### BACKGROUND ART

Generally, for a front cabinet of a thin display device such as a liquid crystal television, a formed product of a resin product is adopted. Then, in order to perform harness holding of speakers and boards of the liquid crystal television, a holding structure such as a rib is needed for the formed product. More specifically, on the liquid crystal television, boards for transmission/reception by infrared rays and the like are arranged in a space other than a display section. These boards are constructed so as to be connected from a connecter section to a board mounted on a liquid crystal module by harnesses. At this time, if boards and harnesses are attached on a production (assembly) line, processes increase, so that the production line which is needed becomes long. Boards and harnesses are, therefore, attached to an appearance product (a cabinet and the like) in advance and, after assembling a liquid crystal module on a production line, work of wiring processing only is to be performed. Such a production line makes it possible to seek shortening of the production line, enabling efficient producing of products even on the short line.

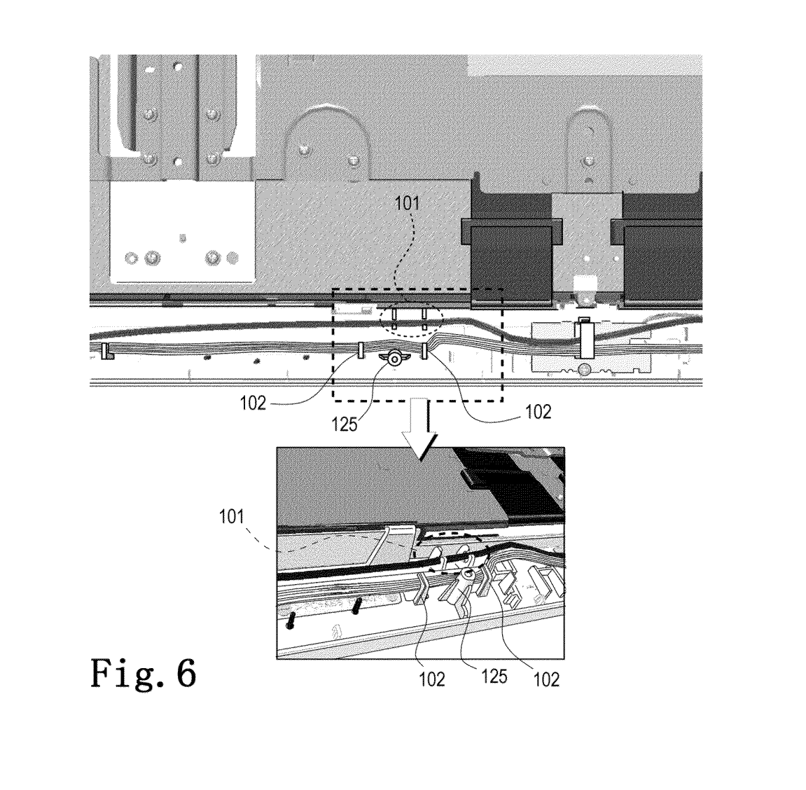

FIG. 6 is a view showing an example of a harness holding structure (a line-shaping structure) according to conventional technology. Here, an area where wires of a speaker and the like are routed at a lower side section of a rear surface of a front cabinet is shown. Here, the wires are divided into two bundles, and a line-shaping rib 101 for one bundle presents a U-shaped sandwich structure which is an opening where a tip thereof has a locking structure. A line-shaping rib 102 for the other bundle presents a structure to hold down the wires from the upper side.

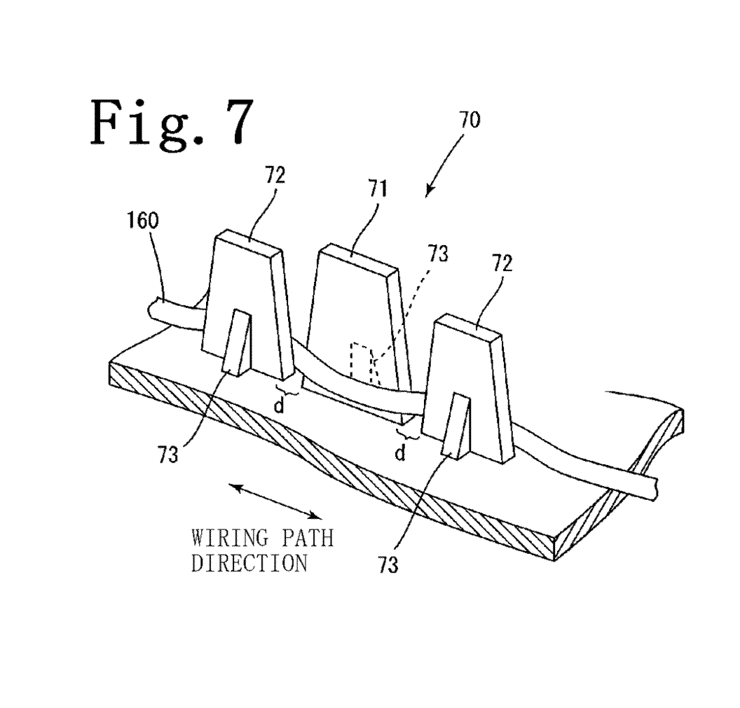

Further, as another technology, as shown in FIG. 7, there is technology whereby a cable 160 is firmly fixed on a cable path as well as certainly prevented from being displaced from locking ribs 70, and, additionally, the locking ribs 70 and locking rib engagement sections in an engagement state function as reinforcement ribs to increase the rigidity of a television cabinet which constitutes an liquid crystal television (for example, refer to PATENT LITERATURE 1). Specifically, as shown in FIG. 7, the cable 160 extended from a speaker is locked in a zigzag manner by each locking rib 70 created on a wiring path on the inside of a front wall, and a front cabinet and a rear cabinet are jointed to engage the locking ribs 70 and the locking rib engagement sections.

### CITATION LIST

### Patent Literature

PATENT LITERATURE 1: Japanese Laid-Open Patent Publication No. 2005-130097

### SUMMARY OF INVENTION

### Technical Problems

There is a problem that as to line-shaping ribs which are used generally, when performing line-shaping, wires are apt to fall apart to be sandwiched between other components. It is possible to widen the diameter of the ribs, however, since fitting of cables becomes worse, functions as ribs become unable to be fully exerted, which is not a realistic measure. Moreover, a boss for attaching a cabinet such as a stand cover can cause wire biting. Though it is also possible to create a rib upward near a boss to prevent lifting up, there is room for improvement in holding performance and another technology has been required.

Additionally, in case of a simple hook structure, cables are not held perfectly, thus the cables can flutter. Therefore, leading to increase of the number of components and increase of work processes, such that a wire holder needed to be used separately, technological countermeasures have been required. Furthermore, in case of a system for press-fitting to a U-shaped rib 101 in FIG. 6, since pressure on cables in the case of press-fitting is high, there was a risk that cables break. Additionally, there was also a problem that harnesses are easily displaced during transportation in a factory. A structure, therefore, has been needed such that harnesses do not flutter after boards and the like are attached in a preceding process to a production line nor are displaced during transportation on the production line.

The present invention has been made in view of circumstances described above, and aims to provide technology for solving the above-described problems.

### Solution to Problem

The present invention is a cabinet for a thin display device having a holding structure of a cable, in which the holding structure includes two ribs having a cable arranged on an upper surface thereof and a hook for holding down the cable arranged on the ribs between the ribs, the two ribs line in a routing direction of the cable to separate by a prescribed interval and each of the ribs includes a regulating section for regulating a position of the cable which is routed, and the hook has a locking section for locking the cable and a sloping surface for guiding arrangement in a holding space which is created by the rib and the hook.

Moreover, the cabinet for a thin display device may include a first opening section which is created between the two ribs and a second opening section which is created so as to be continuous from the first opening section to a protruding part of the hook.

Another aspect of the present invention has the above-described cabinet for a thin display device.

### Advantageous Effects of Invention

According to the present invention, it is possible to provide technology that stably fixes a plurality of harnesses all at once, without using a wire holder.

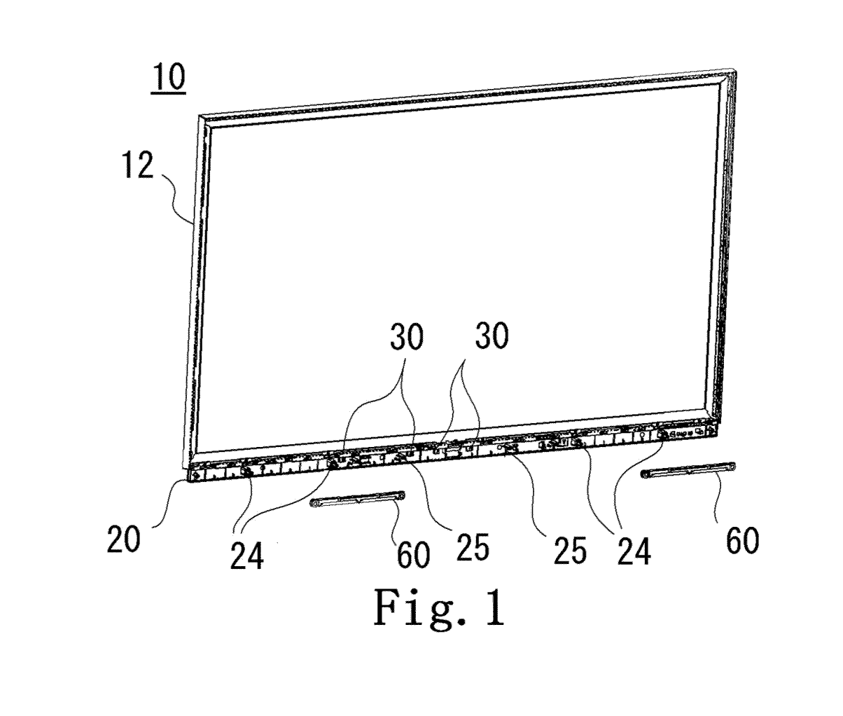

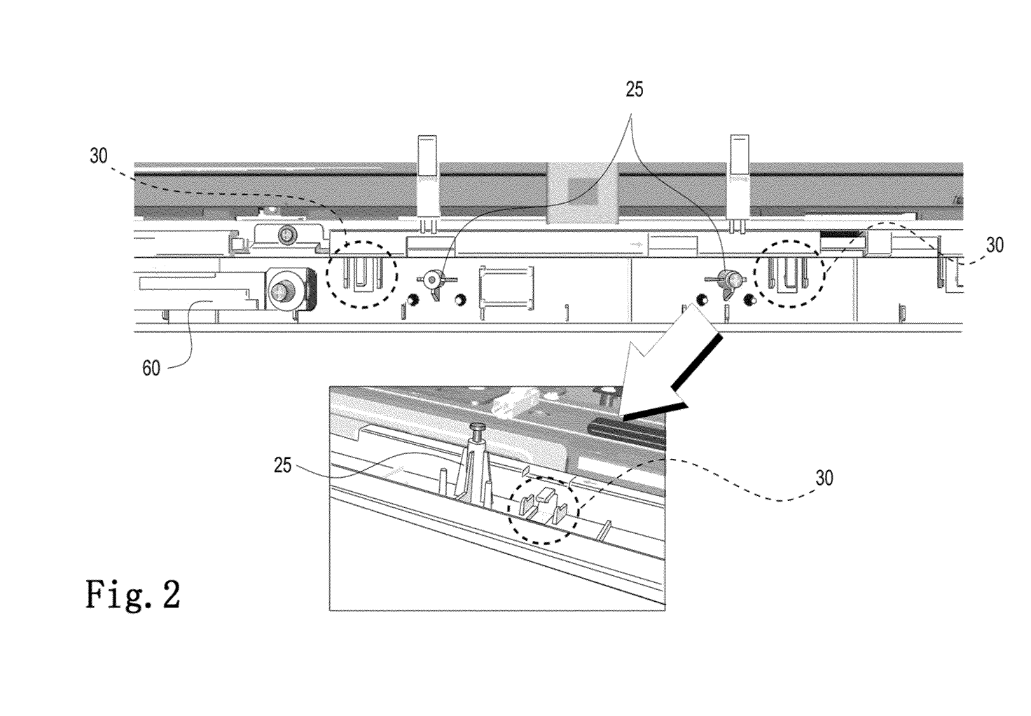

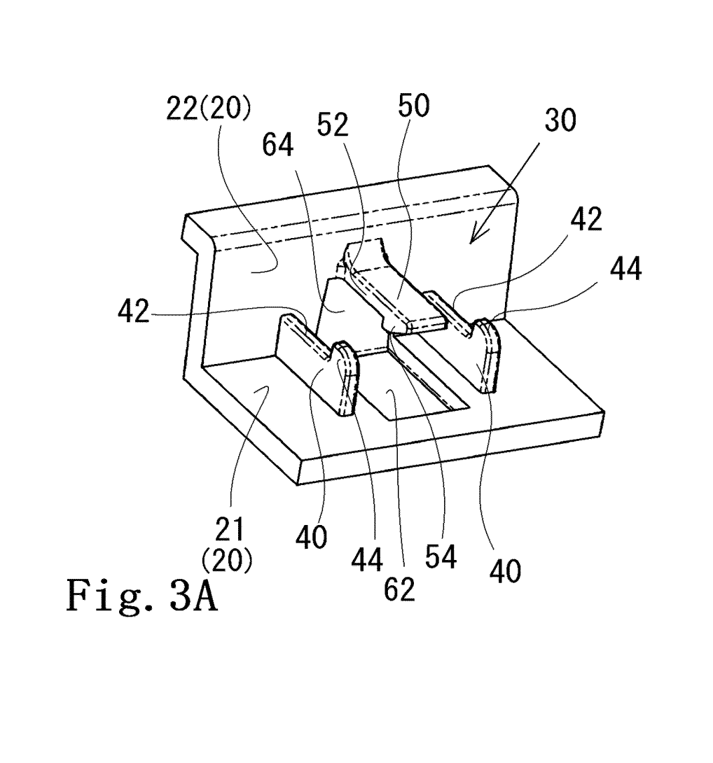

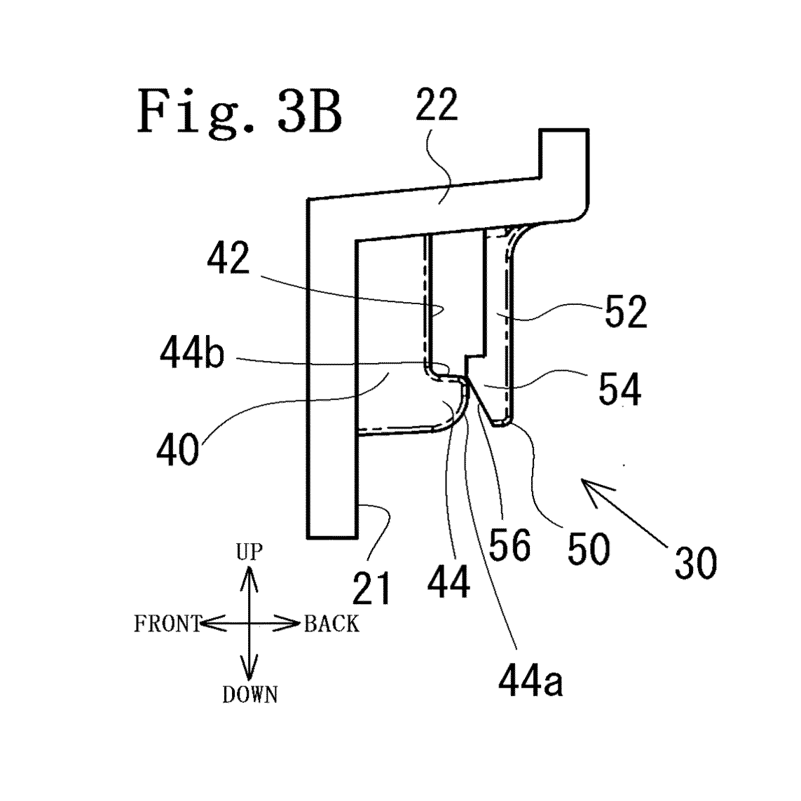

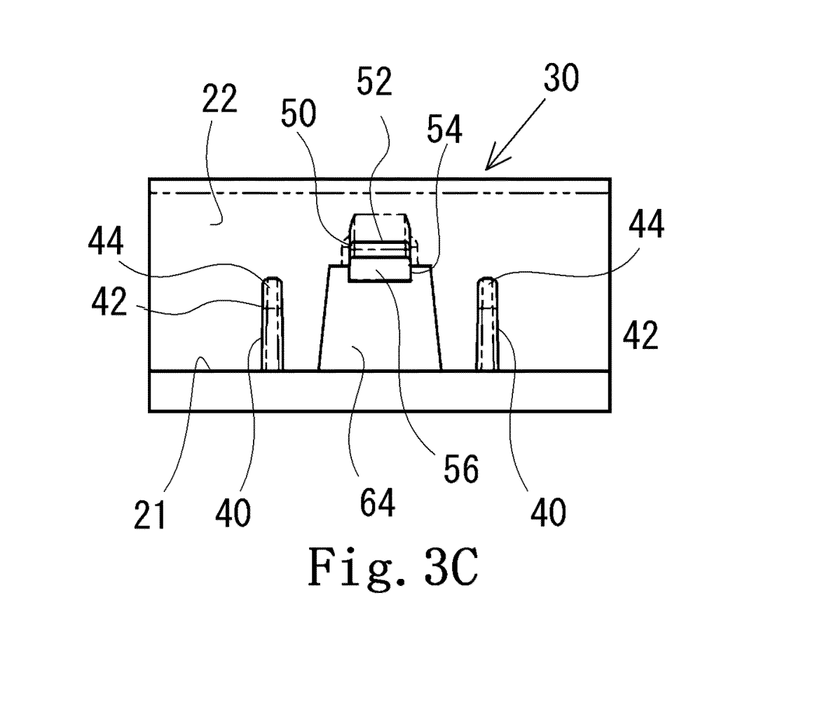

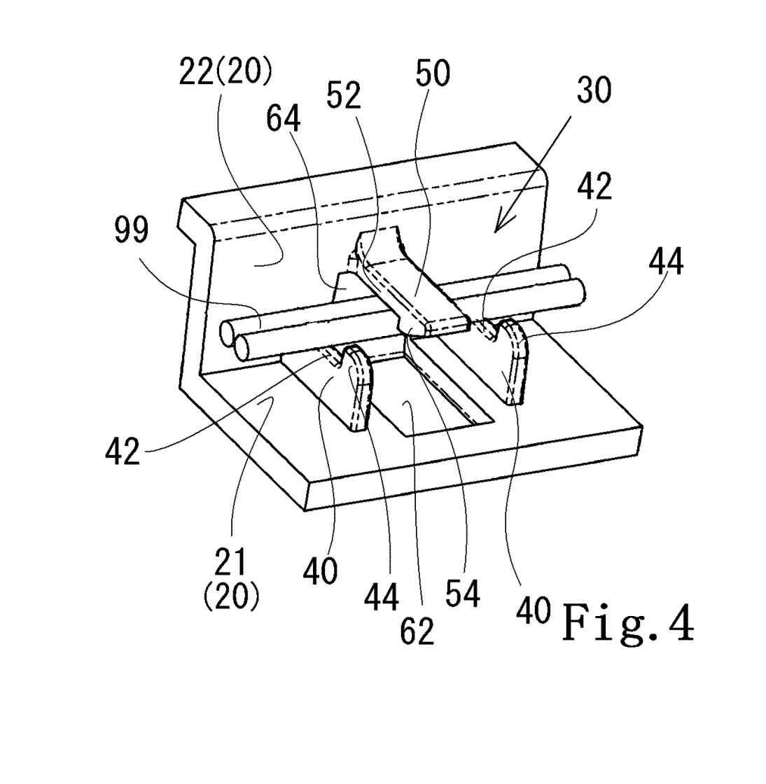

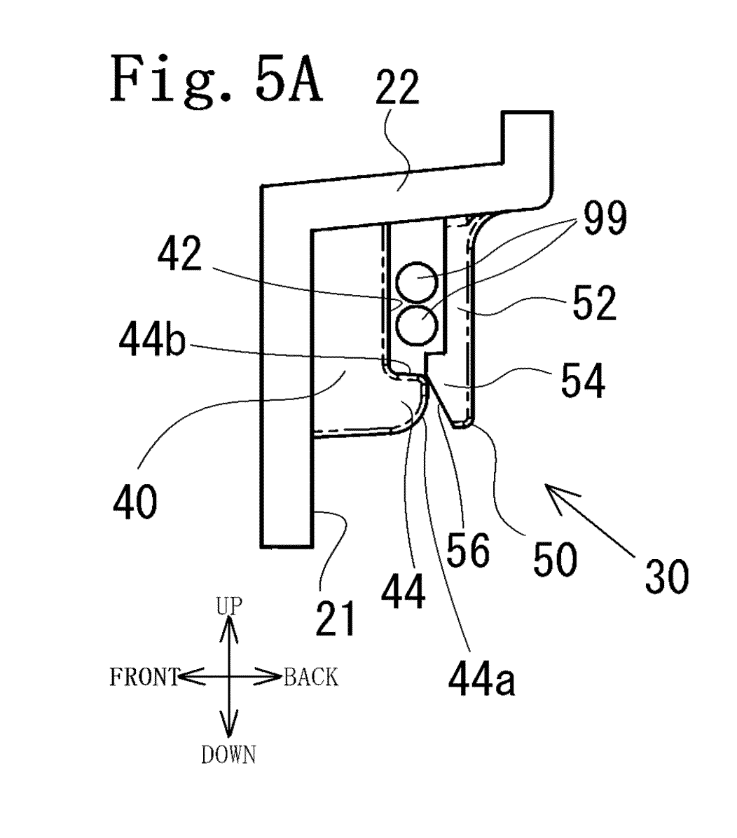

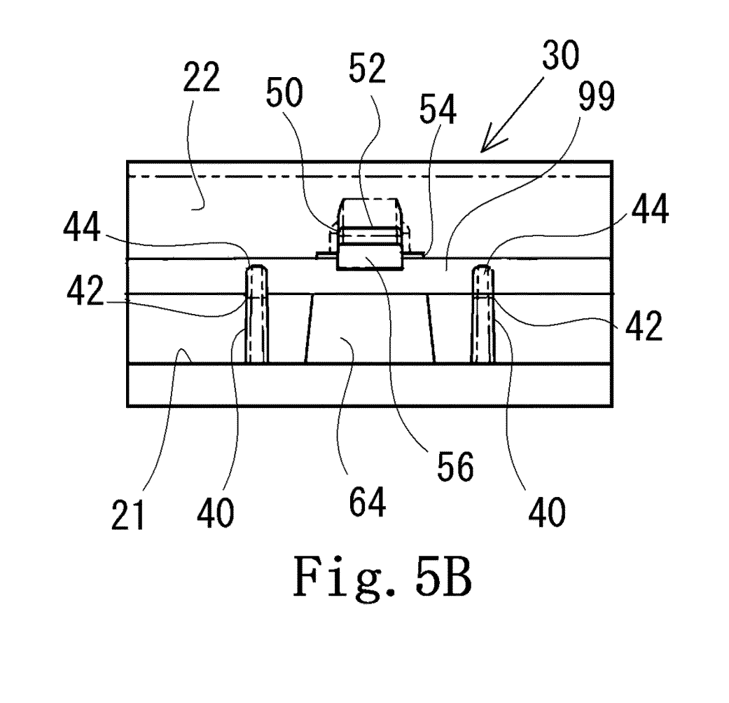

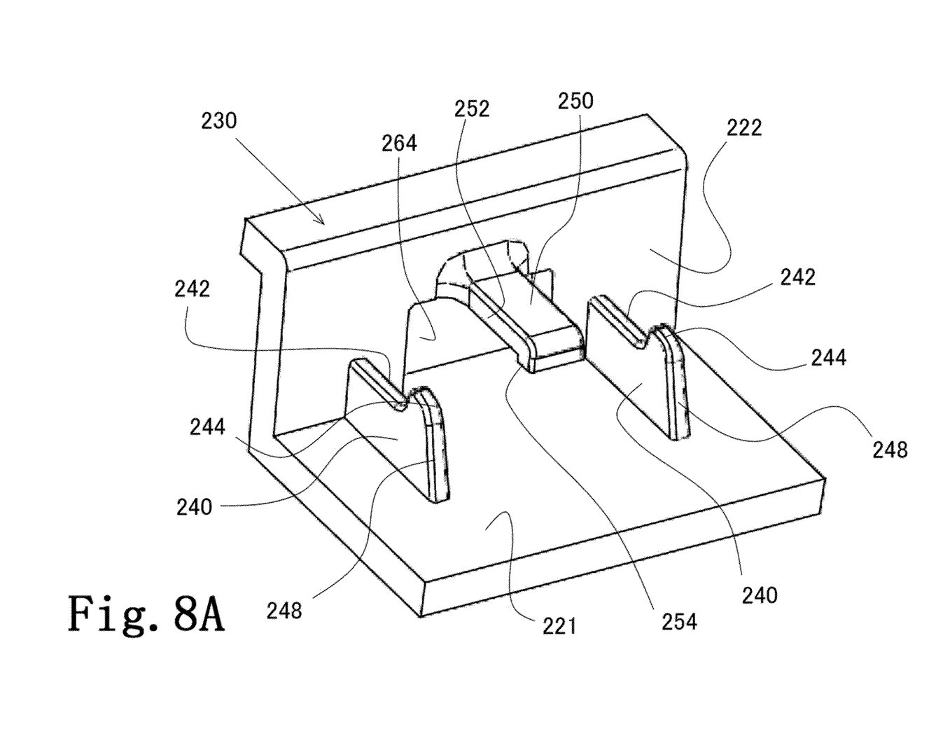

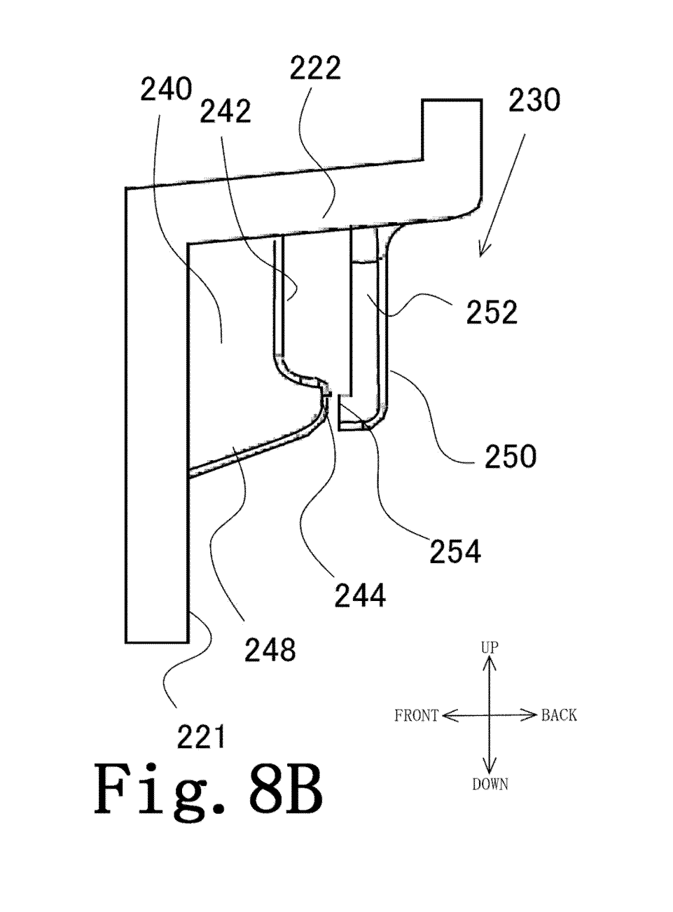

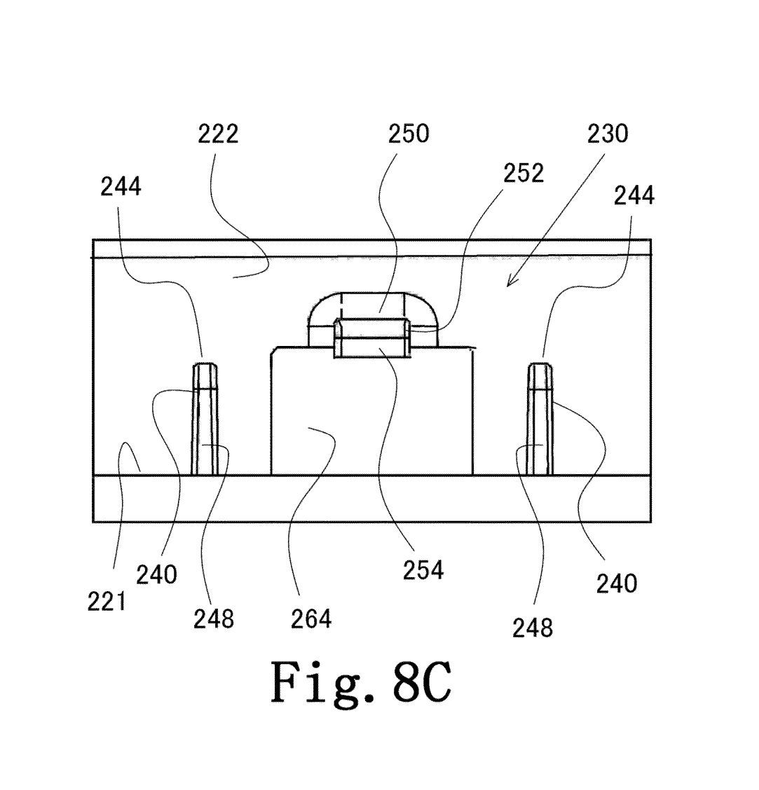

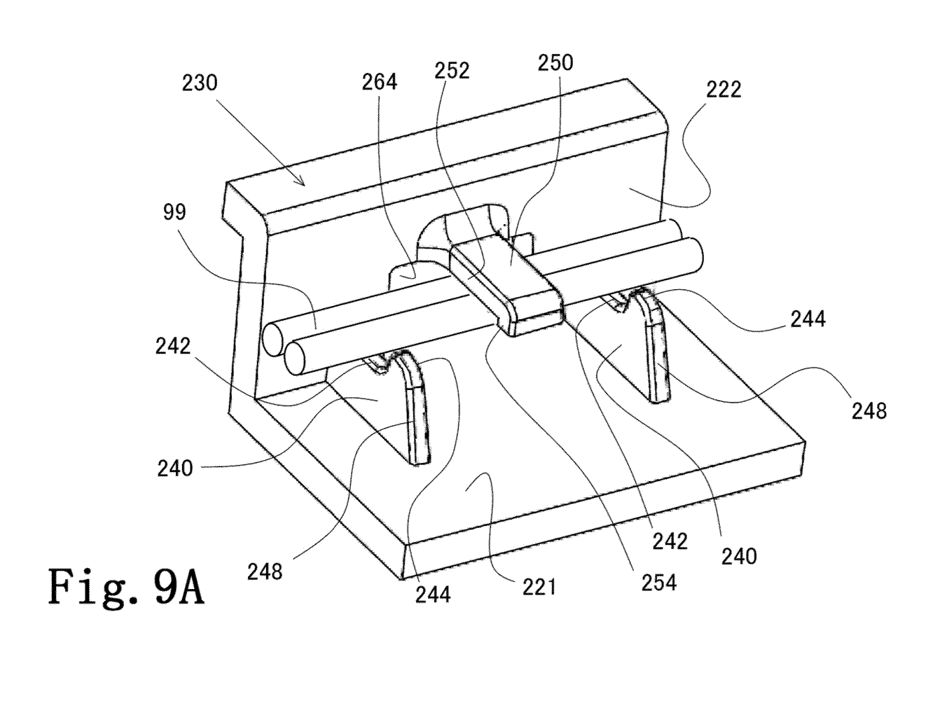

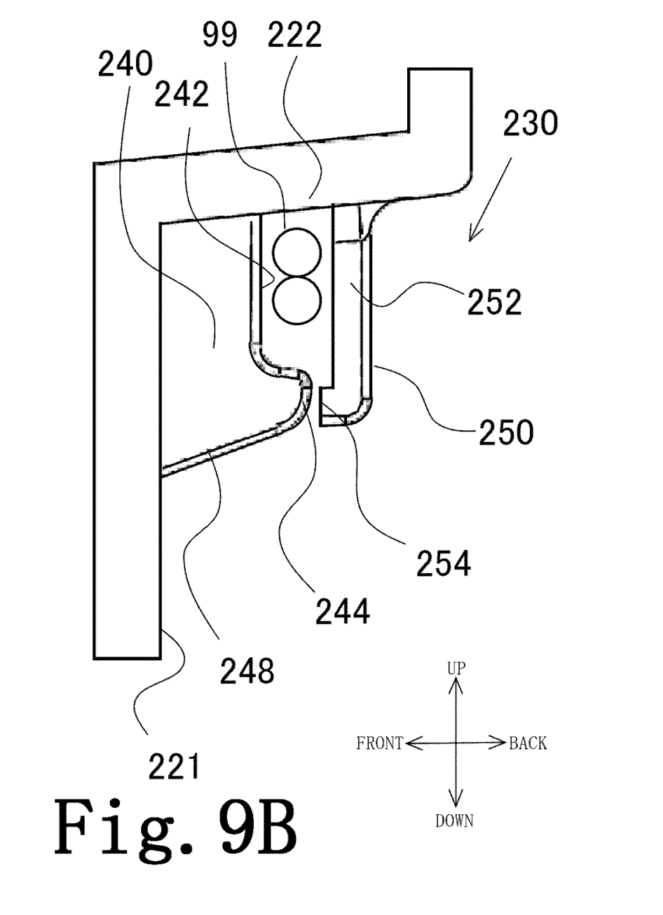

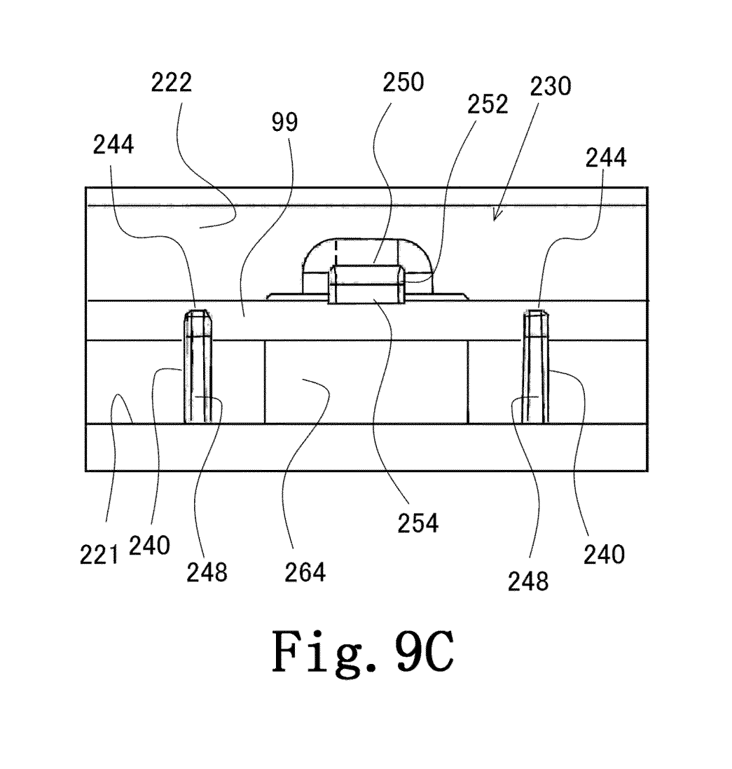

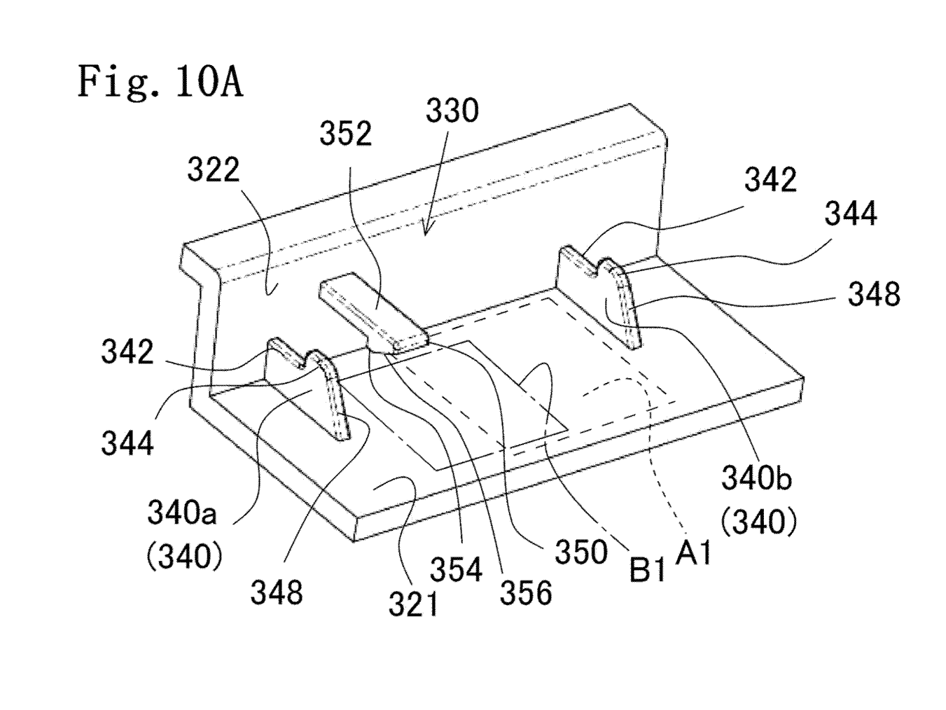

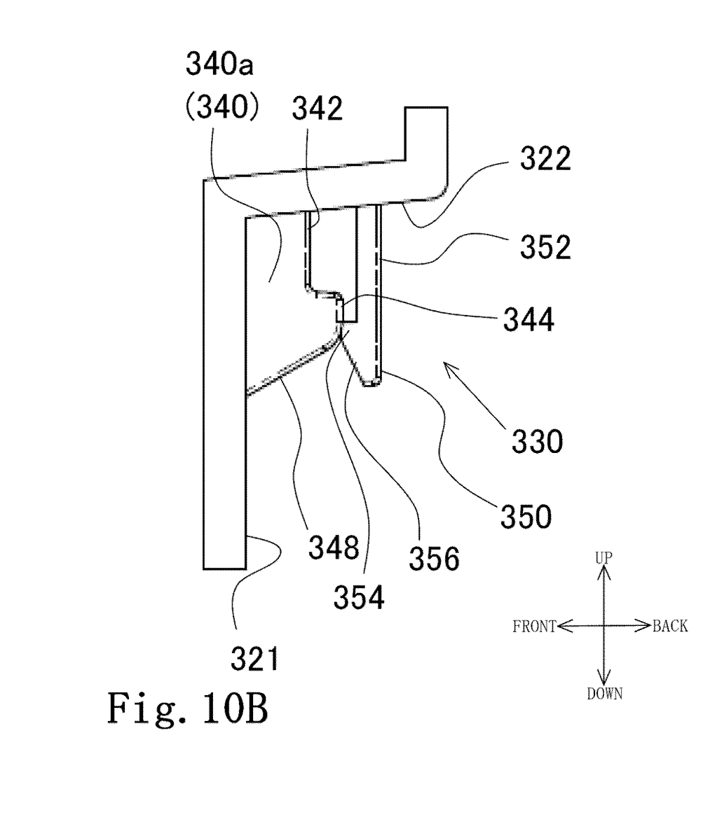

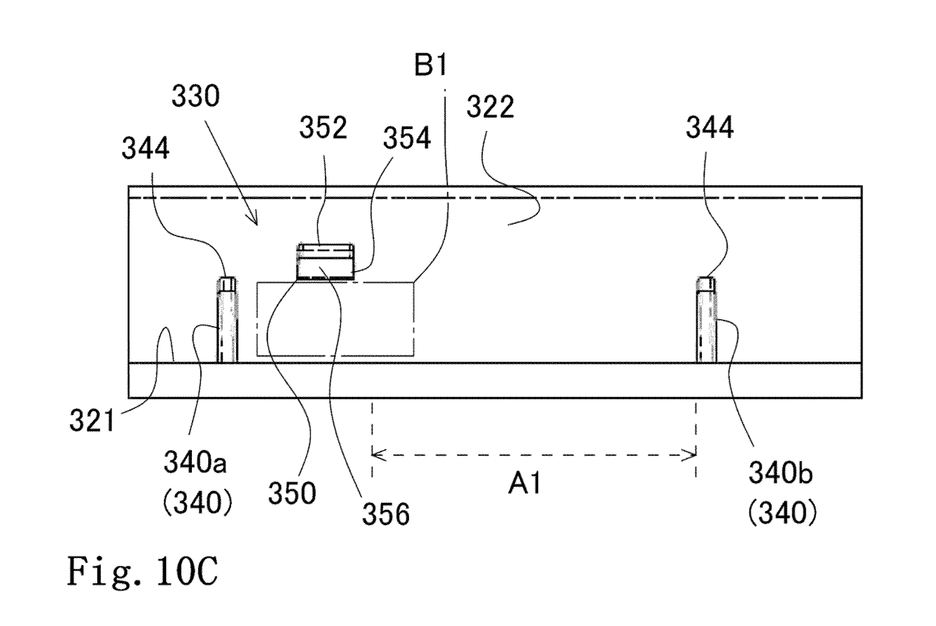

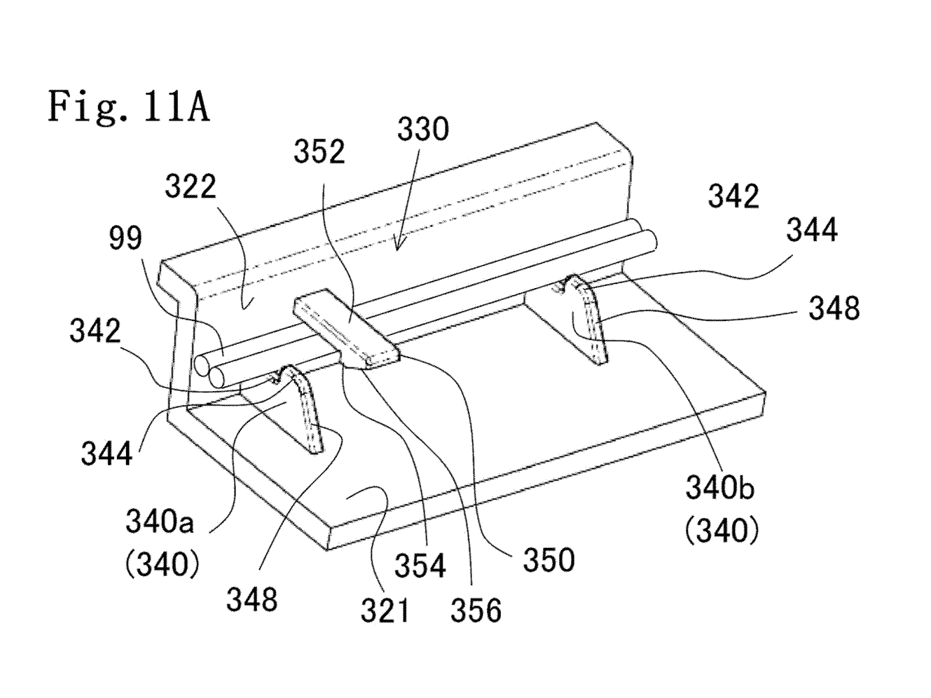

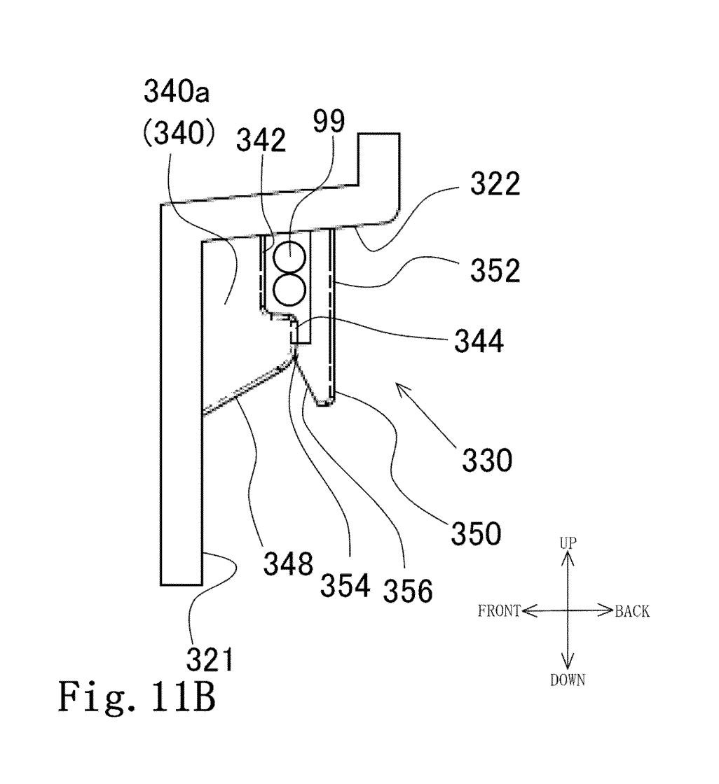

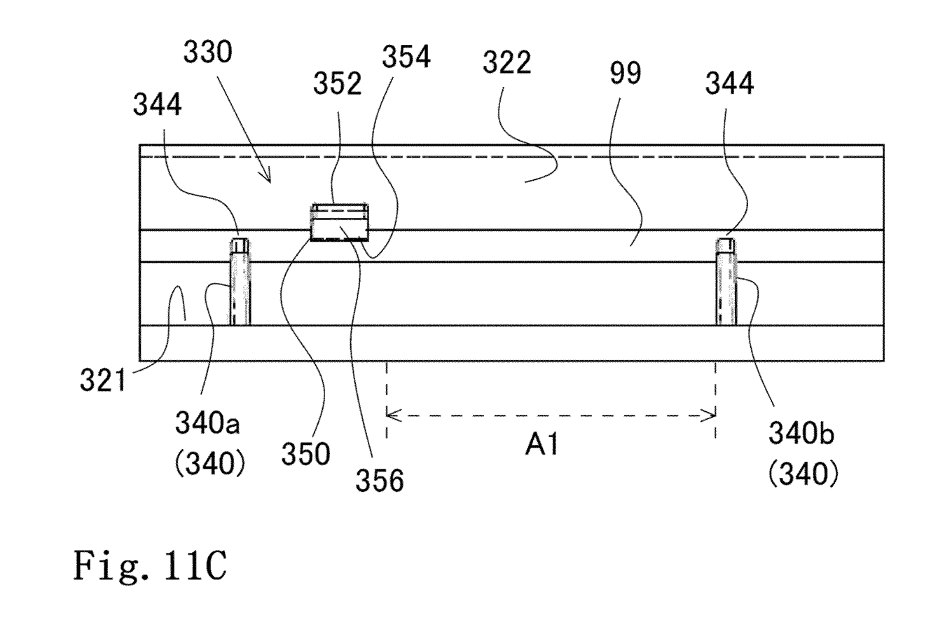

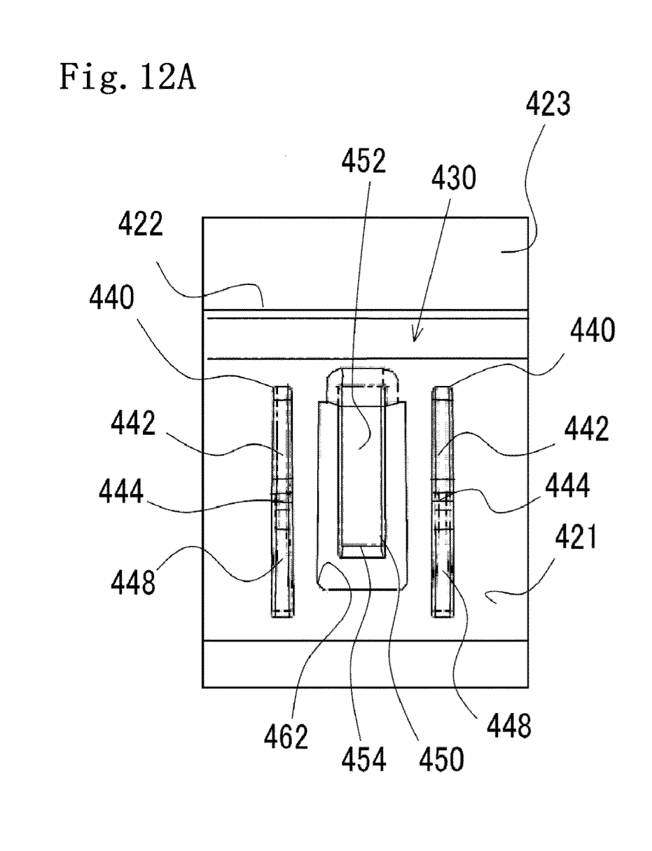

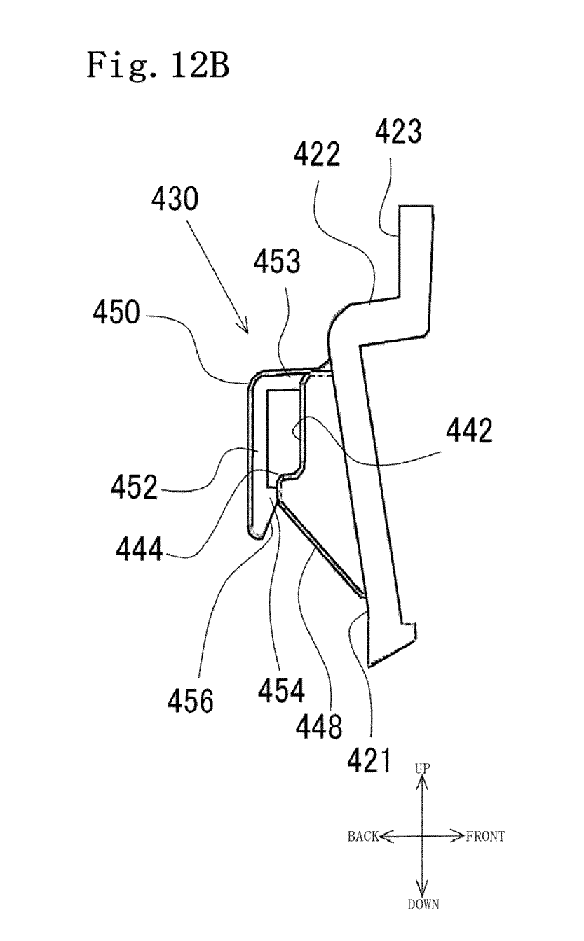

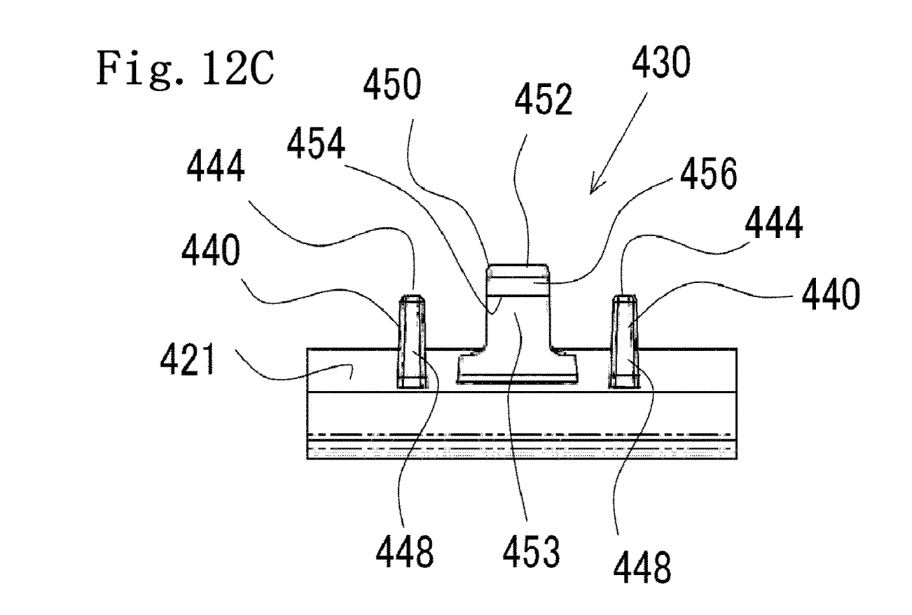

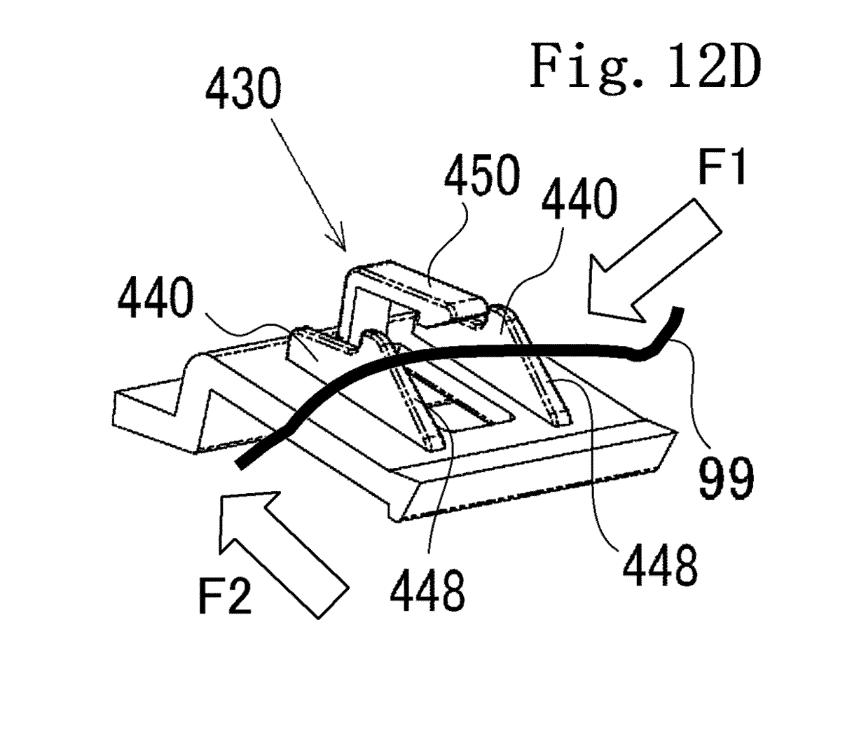

### BRIEF DESCRIPTION OF DRAWINGS

[FIG. 1] is a view showing a rear surface side of a front cabinet of a liquid crystal television according to an embodiment.

[FIG. 2] is a view showing a line-shaping section of the front cabinet according to the embodiment.

[FIG. 3] is a view showing the line-shaping section of the front cabinet according to the embodiment.

[FIG. 4] is a view showing the line-shaping section of the front cabinet in a state where harnesses are routed according to the embodiment.

[FIG. 5] is a view showing the line-shaping section of the front cabinet in a state where the harnesses are routed according to the embodiment.

[FIG. 6] is a view showing a line-shaping section of a front cabinet according to conventional technology.

[FIG. 7] is a view showing a line arrangement structure for a cable according to conventional technology.

[FIG. 8] is a view showing a line-shaping section of a front cabinet according to a modification 1 of the embodiment.

[FIG. 9] is a view showing the line-shaping section of the front cabinet in a state where harnesses are routed according to the modification 1 of the embodiment.

[FIG. 10] is a view showing a line-shaping section of a front cabinet according to a modification 2 of the embodiment.

[FIG. 11] is a view showing the line-shaping section of the front cabinet in a state where harnesses are routed according to the modification 2 of the embodiment.

[FIG. 12] is a view showing a line-shaping section of a front cabinet according to a modification 3 of the embodiment.

### DESCRIPTION OF EMBODIMENTS

Next, description will be given specifically for a mode for carrying out the present invention (hereinafter, simply referred to as an “embodiment”) with reference to drawings. FIG. 1 is a view showing a rear surface side of a front cabinet 12 of a liquid crystal television 10 according to the present embodiment. On the lower side of the front cabinet 12, a front cabinet forming section 20 is attached. Additionally, though not shown here, on a front surface side of the front cabinet 12, a front panel (a decorative panel) of, for example, an aluminum alloy plate is attached. Note that, in the present embodiment, a cabinet for a thin display device is exemplified in a cabinet for the liquid crystal television 10, and also applicable to a plasma display television, an organic EL television, and the like.

In the front cabinet forming section 20, a boss for SP 24, a boss 25 for fixing a stand cover or a rear cabinet, and a line-shaping section 30 are created. At the boss for SP 24, a speaker 60 is fixed. Moreover, at the boss 25, a rear cabinet (not shown) is fixed. At the line-shaping section 30, harnesses (cables) 99 of the speaker 60 and a infrared communication circuit are routed.

FIG. 2 shows the line-shaping section 30 of the front cabinet forming section 20. Moreover, FIG. 3 is a view where the line-shaping section 30 is enlarged to be shown, FIG. 3(a) is a perspective view, FIG. 3(b) is a side view, and FIG. 3(c) is a bottom view. Furthermore, FIG. 4 shows the line-shaping section 30 in a state where the harnesses 99 are routed to FIG. 3(a). In the same manner, FIG. 5(a) and FIG. 5(b) show the line-shaping section 30 in a state where the harnesses 99 are routed to FIG. 3(b) and FIG. 3(c).

As shown, the front cabinet forming section 20 has a first forming wall surface 21 which is parallel to a display surface and a second forming wall surface 22 which is created to be almost perpendicular to the first forming wall surface 21 and created so as to extend in the backward direction by a prescribed length. A back side end section of the second forming wall surface 22 extends more in the upper direction to be fixed to the front cabinet 12.

Then, from the first forming wall surface 21, two plate-shaped ribs 40 are created at a prescribed height in a state to be opposed and separated by a prescribed interval. An end section of the backward side of the rib 40 serves as a routing section 42 where the harnesses 99 are arranged. Moreover, at an end section of the lower side of the routing section 42, a rib locking section 44 which extends in the backward direction is created. A lower side corner section 44a of the rib locking section 44 is round-shaped (or a sloping surface). An upper side end section 44b of the rib locking section 44 extends almost perpendicularly backward.

A side surface part of the upper side of the rib is connected integrally with the second forming wall surface 22. With such a structure, the routing section 42 and the rib locking section 44 are to regulate a position of the harnesses 99.

From the second forming wall surface 22, a hook 50 which stretches out downward is created. The hook 50 is provided with a hold-down section 52 which extends in the downward direction from the second forming wall surface 22 and a hook locking section 54 which is created on the tip side thereof. The hook locking section 54 presents a claw shape inside (the side of the first forming wall surface 21). Moreover, the end section side serves as a guide section 56 where an incline is set so as to be more outward as being downward.

As shown in FIG. 3(b), in positional relationship of the front-back direction, the hold-down section 52 extends from the position where the harnesses 99 are able to be arranged with a little surplus in a space created by the rib 40 and the hook 50. Additionally, the position of the front surface side of the hook locking section 54 almost accords with the position of the backward side of the rib locking section 44. Accordingly, when viewed from the side surface, the harnesses 99 are routed in the space surrounded by the second forming wall surface 22, the routing section 42, the rib locking section 44, the hook locking section 54 and the hold-down section 52.

When routing the harnesses 99 in the above-described space, a worker routes the harnesses 99 so as to insert from the lower side. At this time, by the guide section 56 of the hook locking section 54 and the round shape of the lower side corner section 44a of the rib locking section 44, routing is able to be performed comparatively smoothly with the hold-down section 52 bent. Since, once having been routed, being held by the hook locking section 54 and the rib locking section 44, the harnesses 99 are prevented from being displaced, unless being taken out by bending the hold-down section 52 intentionally. Moreover, adjusting length of the hold-down section 52 makes it possible to adjust detachability of the harnesses 99.

Additionally, in the first forming wall surface 21, as shown, a first opening section 62 which is rectangular is created between the two ribs 40. The width in the horizontal direction of the first opening section 62 is set wider than the width of the hook 50. Moreover, the width in the vertical direction of the first opening section 62 is set slightly longer than the vertical length of the rib 40.

Furthermore, in the second forming wall surface 22, a second opening section 64 which is trapezoid is created so as to be continuous with the first opening section 62 of the first forming wall surface 21 up to a root part of the hold-down section 52.

Since the first and second opening sections 62 and 64 are created to form a shape of a hook, a mold for forming the front cabinet forming section 20 is able to form the hook only with a cavity side and a core side. That is, a complicated mold using a slide core is not needed. Mold cost thus is able to be lowered. Note that, in a case where a component for appearance (a decorative panel) is arranged in the forward side of the front cabinet forming section 20, a structure for hiding the first and second opening sections 62 and 64 is unnecessary. It is particularly effective in a case where the component for appearance is created by a metallic plate (an aluminum alloy plate), because it is difficult to provide a holding structure of the harnesses 99 in the component for appearance.

Furthermore, in prior art, when the harnesses 99 are in contact with the side surface part of the boss 25 and the like, there is a risk that the harnesses 99 protrude to the tip side of the boss during routing work or transportation on a manufacturing line, a prevention measure therefore has been needed. That is, it is needed to sufficiently separate the boss 25 from the harnesses 99, so that there has been a limitation on flexibility of a design. In the present embodiment, however, since the structure is to hold down the harnesses 99, the harnesses 99 does not protrude, and, on the contrary, it is possible to use the boss 25 and the like for movement regulation (line-shaping) of the harnesses 99.

Then, the features of the present embodiment are summarized as below. That is, providing the ribs 40 in the both sides of the hook 50 makes the structure that walls are added in the both sides of the hook 50. By this structure, a structure that the harnesses 99 are sandwiched by the hook in the center and the two ribs 40 in the both sides thereof is able to be realized. As the result, once the harnesses 99 and the like are hooked, stress acts lightly on the harnesses 99, preventing fluttering of the harnesses 99. Additionally, a mold for resin forming of this structure does not need a complicated structure such as a slide core, either, and the shape is able to be made simply and cheaply.

Hereinabove, the present invention has been described based on the embodiment. This embodiment provides an exemplification, and any person with ordinary skill in the art could understand that, for combination of each component thereof and the like, various modifications can be made, and such modifications are also within the scope of the present invention. For example, though the two ribs 40 are to be almost in the same shape, the gist is not limited thereto, and they may have a different shape or different size. Moreover, the position of the hook 50 may be offset, not being in the middle of the two ribs 40. Hereinafter, description will be given for specific structures of modifications with reference to FIGS. 8 through 12. Note that, hereinafter, description will be given mainly for different structures, and description for parts which are common to the above-described embodiment will be properly omitted.

FIG. 8 and FIG. 9 are views showing a line-shaping section 230 according to a modification 1. FIG. 9 shows the line-shaping section 230 in a state where the harnesses 99 are routed to FIG. 8. A point different from the above-described embodiment lies in that there is no opening corresponding to the first opening section 62 in a first forming wall surface 221 and there is only an opening section 264 provided on a protruding part (a root part of a hold-down section 252) of a hook 250 corresponding to the second opening section 64. Then, using this opening section 264, a slide core is extracted at the time of forming.

Moreover, the guide section 56 for smoothly routing the harnesses 99 is not provided on the tip side part (in FIG. 8(b), the lower side end section) of a hook locking section 254 of the hook 250. Instead, a guide section 248 is created with a prescribed incline in the lower side end section of a rib 240. Note that, a structure equivalent to the guide section 56 may be provided in the hook locking section 254. A point that the harnesses 99 are routed to a routing section 242 of a rib locking section 244 is the same.

According to the present modification, it is possible to stably fix a plurality of harnesses 99 all at once without using a wire holder. Additionally, fixing the harnesses 99 to the line-shaping section 230 is easy. It is possible to make a harness holding structure without need of another appearance component in the front surface side of the liquid crystal television 10. Further, at the time of forming, it is possible to set an extracting direction of a slide core which is a molding part needed for forming the hook 250 not to the path direction of the harnesses 99 but to extract in the side surface direction, so that a distance between the two ribs 240 and the hook 250 in the center is able to be kept as a proper distance, enabling maintaining stress lightly put to the harnesses 99. Moreover, since the slide core is used, it becomes possible to make a desired shape without having an opening section in an area opposing to the hook 250 (a cavity side) on the first forming wall surface 221, and also to discontinue other components such as a cover and decoration on the front surface which were conventionally needed for hiding the opening section.

FIG. 10 and FIG. 11 are views showing a line-shaping section 330 according to a modification 2. FIG. 11 shows the line-shaping section 330 in a state where the harnesses 99 are routed to FIG. 10. Note that, in FIG. 10, an area B1 of a slide core for forming a hook 350 is shown.

For a general mold structure, in order to make a shape of the hook 350, an opening section (the first opening section 62 or the second opening section 64) has been needed, but, in order to form the hook 350, by using a slide core like being extracted to the side surface, which is like being extracted to the right side direction in FIG. 10(c), it is possible to make a shape of the hook 350 without need of an opening section in a first forming wall surface 321 nor a second forming wall surface 322.

Since, among two ribs 340a and 340b, the rib 340b in a slide core extracting direction side needs a slide core extracting space (an area A1), an interval from the hook 350 (the area A1) is to be wide to some extent. Note that, a guide section 356 is provided in a hook locking section 354 of the hook 350 to cause the harnesses 99 to be routed easily in combination with inclination of the ribs 340a and 340b on the both sides (guide sections 348). Since a space for extracting a slide core in the horizontal direction is needed, one of the ribs 340a and 340b on the both sides needs distance from the hook 350 to some extent, but it is possible to properly hold the harnesses 99 with three points of the hook 350 and the ribs 340a and 340b on the both sides.

Since, by using the slide core like this, it is possible to realize a desired shape without having an opening section, appearance quality of products is not damaged. Moreover, it becomes possible to discontinue other components such as a cover and decoration for covering the opening section.

FIG. 12 is a view showing a line-shaping section 430 according to a modification 3. In the present modification, a pick-up shape of the harnesses 99 is created in a rib 440.

As shown, the two ribs 440 are created in a first forming wall surface 421. Moreover, a hook 450 is created so as to protrude from the first forming wall surface 421. Specifically, a hook base section 453 is created so as to extend almost perpendicularly backward (in FIG. 12 (b), in the left direction) only by a prescribed length from the first forming wall surface 421. In addition, a hold-down section 452 only of a prescribed length is created so as to bend downward at a right angle. A hook locking section 454 which has a guide section 456 is created in the tip of the hold-down section 452. Additionally, in an area opposing to the hold-down section 452 of the first forming wall surface 421, an opening section 464 which is formed to extract a slide core used for forming the hook 450 in a prescribed shape is provided.

Note that, because a second forming wall surface 422 is created so as to face forward, the hook base section 453 is provided to the hook 450, but, in a case where a second forming wall surface is created so as to face backward as the embodiment, a structure is to have no hook base section 453. Moreover, a routing section 442 and a rib locking section 444 are the same as the above-described embodiment.

Then, as shown in FIG. 12(d), by simple work of moving the harnesses 99 along the guide section 448 (a direction of an arrow F2 which is shown), as pressing to a guide section 448 of the rib 440 (a direction of an arrow F1 which is shown), it is possible to properly route the harnesses 99.

### REFERENCE SIGNS LIST

10 liquid crystal television
12 front cabinet
20 front cabinet forming section
21, 221, 321, 421 first forming wall surface
22, 222, 322, 422 second forming wall surface
24 boss for SP
25 boss
30, 230, 330, 430 line-shaping section (holding structure)
40, 240, 340, 340a, 340b, 440 rib
42, 242, 342, 442 routing section
44, 244, 344, 444 rib locking section
44a lower side corner section
44b upper side end section
50, 250, 350, 450 hook
52, 252, 352, 452 hold-down section
54, 254, 354, 454 hook locking section
56, 248, 348, 356, 448, 456 guide section
60 speaker
62 first opening section
64 second opening section
99 harness (cable)
264, 462, 464 opening section
453 hook base section

1. A cabinet for a thin display device having a holding structure of a cable, wherein
the holding structure includes two ribs having a cable arranged on an upper surface thereof and a hook for holding down the cable arranged on the ribs between the ribs,
the two ribs line in a routing direction of the cable to separate by a predetermined interval and each of the ribs includes a regulating section for regulating a position of the cable which is routed, and
the hook has a locking section for locking the cable and a sloping surface for guiding arrangement in a holding space which is created by the rib and the hook.

2. The cabinet for a thin display device as defined in claim 1, comprising;
a first opening section which is created between the two ribs, and
a second opening section which is created so as to be continuous from the first opening section to a protruding part of the hook.

3. A thin display device having the cabinet for a thin display device as defined in claim 1.

4. A thin display device having the cabinet for a thin display device as defined in claim 2.
